(19) United States
(12) Patent Application Publication
(10) Pub. No.: US 2024/0345739 A1
(43) Pub. Date: Oct. 17, 2024

(54) INFORMATION PROCESSING DEVICE

(71) Applicant: TOYOTA JIDOSHA KABUSHIKI KAISHA, Toyota-shi (JP)

(72) Inventors: Tomoaki KARASAWA, Matsudo-shi (JP); Junichiro TAMAO, Tokyo (JP)

(73) Assignee: TOYOTA JIDOSHA KABUSHIKI KAISHA, Toyota-shi (JP)

(21) Appl. No.: 18/420,053

(22) Filed: Jan. 23, 2024

(30) Foreign Application Priority Data
Apr. 14, 2023 (JP) 2023-066452

(51) Int. Cl. G06F 3/06; G11C 7/04

(52) U.S. Cl. CPC G06F 3/0616; G06F 3/0619; G06F 3/0661; G06F 3/0679; G11C 7/04; G06F 2201/81

(57) ABSTRACT

The information processing device manages a non-volatile memory that can be rewritten in units of cells. The information processing device includes a CPU as an execution device. When the remaining number of times until the number of times of rewriting of the cell reaches the upper limit is set as the rewrite life, CPU executes a process of acquiring the temperature of the cell requested to be written and a process of calculating the rewrite life based on the acquired temperature.

### CROSS-REFERENCE TO RELATED APPLICATION

This application claims priority to Japanese Patent Application No. 2023-066452 filed on Apr. 14, 2023, incorporated herein by reference in its entirety.

### BACKGROUND

### 1. Technical Field

The disclosure relates to an information processing device.

### 2. Description of Related Art

Japanese Unexamined Patent Application Publication No. 2022-55127 (JP 2022-55127 A), for example, describes an apparatus for predicting, based on temperature and so forth, a rewrite life of a semiconductor memory device that is non-volatile memory in which data is rewritable.

### SUMMARY

There is known non-volatile memory in which data is rewritable in increments of cells, such as a NOR flash memory, for example. In this type of non-volatile memory, when writing to a cell is performed in a state in which temperature of the cell is high, the rewrite life of the cell is shorter than when writing to the cell is performed in a state in which the temperature of the cell is low. With regard to this point, the rewrite life predicted by the apparatus described in the above JP 2022-55127 A is the life of the entire memory device. Accordingly, the rewrite life cannot be calculated in increments of cells.

An information processing device that solves the above problem is an information processing device for managing non-volatile memory that is rewritable in increments of cells.

The information processing device includes an execution device that, with a remaining count of times until a rewrite count of the cell reaches an upper limit value set as a rewrite life, executes acquiring a temperature of a cell regarding which writing is requested, and calculating the rewrite life based on the temperature that is acquired.

According to the disclosure, the rewrite life can be calculated in increments of cells.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a schematic diagram illustrating a configuration of an information processing device according to an embodiment;

FIG. 2 is a flowchart illustrating a procedure of processing executed by the information processing device according to the embodiment;

FIG. 3 is a graph showing a temperature-coefficient in a modification of the embodiment; and

FIG. 4 is a graph showing a temperature coefficient in a modification of the embodiment.

### DETAILED DESCRIPTION OF EMBODIMENTS

### Configuration of Information Processing Device

An embodiment of an information processing device will be described below with reference to the drawings.

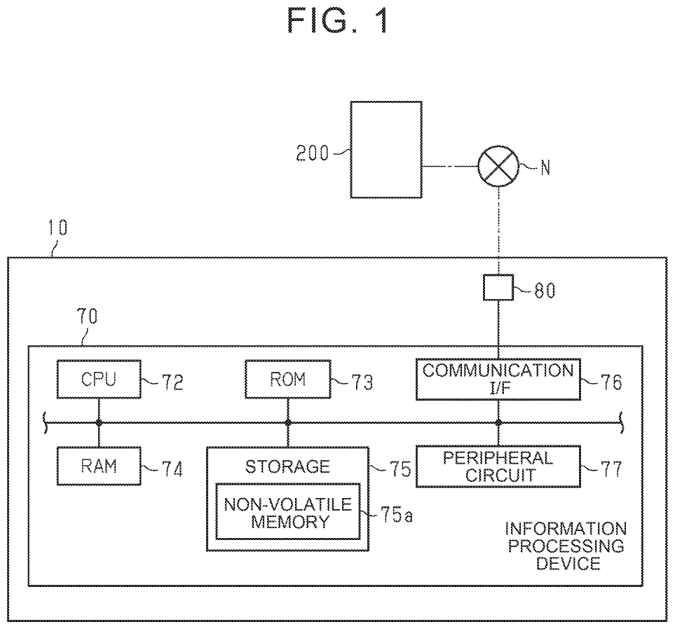

As illustrated in FIG. 1, the vehicle 10 includes an information processing device 70.

The information processing device 70 is a computer including a CPU 72, ROM 73, RAM 74, a storage 75, a communication interface 76, and peripheral circuitry 77, which are central processing units, and are capable of communicating with each other via an internal bus.

The storage 75 includes a non-volatile memory 75a capable of rewriting data on a cell-by-cell basis. The non-volatile memory 75a is, for example, a NOR flash memory.

The communication interface 76 is connected to an external bus. A communication device 80 is connected to the external bus. The communication device 80 is connected to the network N by wireless communication. A data center 200 including a server or the like is connected to the network N.

The peripheral circuit 77 includes a circuit that generates a clock signal that defines an internal operation, a power supply circuit, a reset circuit, and the like.

The information processing device 70 manages writing, reading, deleting, and the like of data to and from the non-volatile memory 75a of the storage 75 by CPU 72 executing the program stored in ROM 73. In the present embodiment, CPU 72 that performs such control is an execution device.

### Calculation of Cell Rewrite Life

When the number of times of rewriting of the cells included in the non-volatile memory 75a until the number of times of rewriting reaches a predetermined upper limit is set as the rewrite life RL, the information processing device 70 executes a process of calculating the rewrite life RL for each cell.

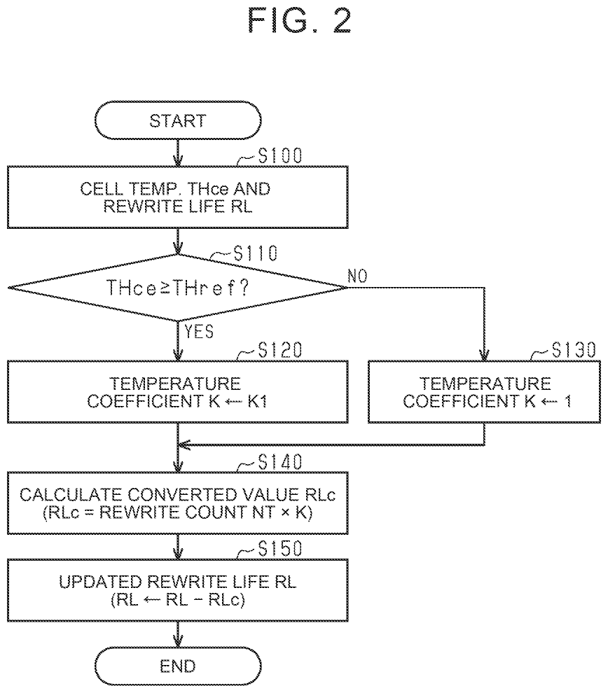

FIG. 2 shows a process sequence for calculating the rewrite life RL. The process illustrated in FIG. 2 is executed by CPU 72 every time a write request is made to a cell of the non-volatile memory 75a. In addition, hereinafter, a step number of each processing is represented by a number prefixed with “S”.

In the series of processes illustrated in FIG. 2, CPU 72 first acquires the cell temperature THce and the present rewrite life RL of the cell in which the write request is generated (S100). The cell temperature THce is a temperature of a cell in which a data-writing request has occurred. This temperature is the temperature of the cell itself, but may also be the temperature near the cell.

Next, CPU 72 determines whether or not the obtained cell temperature THce is equal to or higher than a predetermined reference temperature THref (S110). The reference temperature THref is an upper limit value of the cell temperature at which the effect on the lifetime of the cell is sufficiently small, and is an adaptation value.

In S110 process, when CPU 72 determines that the cell temperature THce is equal to or higher than the reference temperature THref (S110: YES), CPU 72 substitutes the first temperature coefficient K1 for the temperature coefficient K (S120).

When the cell temperature THee is high, the temperature coefficient K is a value for converting the rewrite count NT of the cell requested to be written so that the value of the converted value RLc to be described later becomes larger than that in the case where the cell temperature THce is low. The first temperature coefficient K1 is an adaptation value in which a value larger than “1” is set in advance. More specifically, the first temperature coefficient K1 is: That is, the first temperature coefficient K1 is a coefficient for converting the subtraction value of the rewrite life of the cell when the cell is written in the temperature range equal to or higher than the reference temperature THref into the subtraction value of the rewrite life of the cell when the cell is written in the temperature range lower than the reference temperature THref. For example, when the subtraction value of the rewrite life of the cell when the cell is written in the temperature range equal to or higher than the reference temperature THref is five times the same subtraction value in the temperature range lower than the reference temperature THref, the value of the first temperature coefficient K1 is set to “5”.

In S110 process, when CPU 72 determines that the cell temperature THce is less than the reference temperature THref (S110: NO), CPU 72 substitutes “1” for the temperature coefficient K (S130).

Upon completion of S120 process or S130 process, CPU 72 then calculates a converted value RLc (S140). The converted value RLc is a value obtained by multiplying the rewrite count NT of the cell that is requested to be written this time by the temperature coefficient K calculated in S120 process or S130 process. Here, since this process is executed every time a write request to the cell is made, the rewrite count NT in S140 is “1”.

Next, CPU 72 updates the rewrite life RL (S150). In S150 process, CPU 72 calculates a value obtained by subtracting the converted value RLc from the rewrite life RL obtained in S100 process. Then, by substituting the calculated value into the rewrite life RL, the rewrite life RL of the cell in which the write request is generated is updated.

When S150 process is finished, CPU 72 ends the process once. When the rewrite life RL after being updated in S150 process is less than the predetermined upper limit, CPU 72 receives a write request for the current data to the cell.

### Action and Effect

The action and effect of the present embodiment will be described.

(1) CPU 72 calculates the rewrite life RL of the cell based on the cell temperature THce of the cell that is requested to be written. Therefore, it is possible to accurately calculate the rewrite life in units of cells.

(2) CPU 72 calculates a value obtained by multiplying the rewrite count NT of the cell requested to be written by the temperature coefficient K as the converted value RLc. Further, CPU 72 updates the rewrite life RL by subtracting the converted value RLc from the rewrite life RL. When the acquired cell temperature THce is high, the temperature coefficient K is a value for converting the rewrite count NT of the cell requested to be written so that the value of the converted value RLc becomes larger than that in the case where the acquired cell temperature THce is low.

Therefore, when the cell temperature THce of the write-requested cell is higher than or equal to the reference temperature THref, the temperature coefficient K is set to be larger than when the cell temperature THce is lower than the reference temperature THref. When the value of the temperature coefficient K increases, the value of the converted value RLc increases, and the subtracted value of the rewrite life RL increases. Therefore, when the cell temperature THce is high, the rewrite life RL of the cell to be calculated is shortened quickly. Therefore, the rewrite life RL of the temperature-affected cell can be accurately calculated.

### Modifications

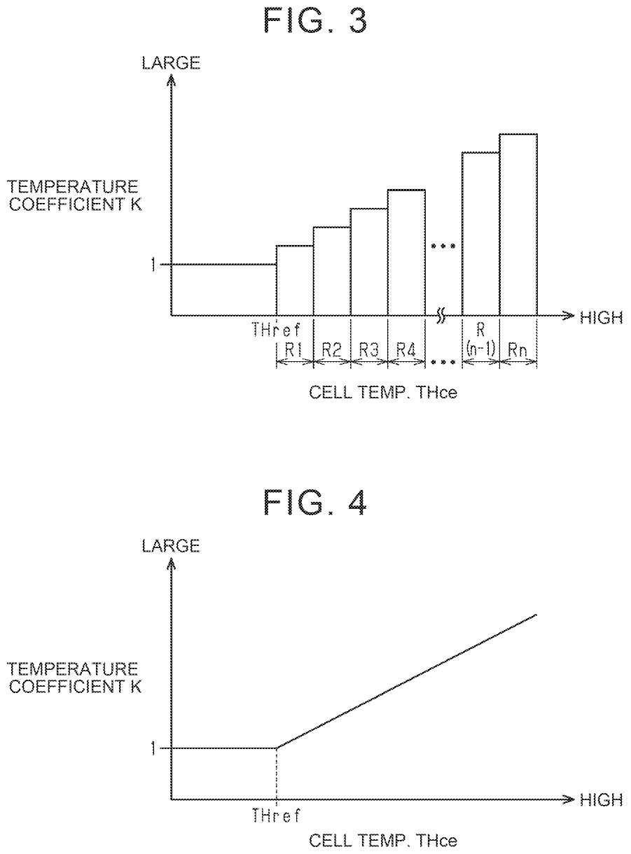

Note that the above embodiment can be implemented with the following modifications. The above embodiment and the following modifications can be combined with each other within a technically consistent range to be implemented.
The temperature coefficient K is set for each temperature segment, and the value of the temperature coefficient K may be set so that the value of the converted value RLc becomes larger in the higher temperature segment.
   FIG. 3 shows an example of this modification. As shown in FIG. 3, when the temperature is less than the reference temperature THref, the temperature coefficient K is set to “1”. On the other hand, above the reference temperature THref, the temperature regions are divided into n from R1 to Rn, and the temperature coefficient K is set for each temperature segment. Then, the value of the temperature coefficient K is set for each temperature segment so that the value of the converted value RLc becomes larger in the higher temperature segment. That is, the value of the temperature coefficient K is set in advance so that the value of the temperature coefficient K increases as the temperature classification increases. Then, CPU 72 acquires the temperature coefficient K set in the temperature category including the acquired cell temperature THce. According to this modification, since the temperature coefficient K is variously set according to the cell temperature THce, the rewrite life RL of the cell affected by the temperature can be calculated more accurately.

The temperature coefficient K may be a value obtained by dividing an upper limit value of the number of times of rewriting of the cell in the reference temperature THref by an upper limit value of the number of times of rewriting of the cell in the acquired cell temperature THce. The upper limit of the number of times the cell is rewritten in the acquired cell temperature THce can be known through an Arrhenius model equation, a preliminary test, or the like. The upper limit value of the number of times of rewriting of the cell in the reference-temperature THref is a known designed value or the like. Then, CPU 72 calculates the temperature coefficient K based on the cell temperature THce.

FIG. 4 shows an example of the temperature coefficient K in this modification example. As shown in FIG. 4, below the reference temperature THref, the temperature coefficient K is set to “1”. On the other hand, at the reference temperature THref or higher, the value of the temperature coefficient K is a value larger than “1”, and is variably set so that the higher the cell temperature THce, the larger the value. According to this modification, since the temperature coefficient K is precisely calculated according to the cell temperature THce, the rewrite life RL of the cell affected by the temperature can be calculated with higher accuracy.
The temperature coefficient K below the reference temperature THref was set to “1”. In addition, in the temperature range below the reference temperature THref, the value of the temperature coefficient K may be set to a value smaller than “1”, and the value may be variably set so as to decrease as the cell temperature THce decreases.
In the above embodiment, the rewrite life RL is updated every time a write request is made to the cell. In addition, the rewrite life RL may be updated after a plurality of X times of writing to the cell. In this modification, the value of “X” is substituted as the value of the rewrite count NT.

A non-volatile memory 75a that can be rewritten in units of cells is a NOR flash memory, but may be another memory, for example, a EEPROM.
The information processing device configured as a computer includes a CPU 72 and a ROM 73, and is not limited to a device that executes a software process. For example, a dedicated hardware circuit such as an application-specific integrated circuit (ASIC) may be provided to perform hardware processing for at least part of what is software processed in the above embodiment. That is, the information processing device may have any one of the following configurations (a) to (c). (a) A processing device for executing all of the above processing according to a program, and a program storage device such as a read only memory (ROM) that stores the program. (b) A processing device and a program storage device for executing part of the above processing according to a program, and a dedicated hardware circuit for executing the remaining processing. (c) A dedicated hardware circuit for executing all of the above processing. Here, there may be a plurality of software execution devices provided with the processing device and the program storage device, or may be a plurality of dedicated hardware circuits.

What is claimed is:

1. An information processing device for managing non-volatile memory that is rewritable in increments of cells, the information processing device comprising an execution device that, with a remaining count of times until a rewrite count of a cell reaches an upper limit value set as a rewrite life, executes
acquiring a temperature of a cell regarding which writing is requested, and
calculating the rewrite life based on the temperature that is acquired.

2. The information processing device according to claim 1, wherein:
the execution device executes
calculating a value, obtained by multiplying the rewrite count of the cell regarding which writing is requested, by a predetermined temperature coefficient, as a conversion value, and
updating the rewrite life by subtracting the conversion value from the rewrite life; and
the temperature coefficient is a value for converting the rewrite count of the cell regarding which writing is requested such that, when the temperature that is acquired is high, a value of the conversion value is greater than when the temperature that is acquired is low.

3. The information processing device according to claim 2, wherein:
the temperature coefficient is set for each temperature segment, the value of the temperature coefficient being set such that the higher the temperature segment is, the greater the value of the conversion value is; and
the execution device acquires the temperature coefficient set in a temperature segment in which the temperature that is acquired is included.

4. The information processing device according to claim 2, wherein:
the temperature coefficient is a value obtained by dividing an upper limit value of the rewrite count of the cell at a reference temperature that is set in advance, by an upper limit value of the rewrite count of the cell at the temperature that is acquired; and
the execution device calculates the temperature coefficient based on the temperature that is acquired.

5. The information processing device according to claim 1, wherein the non-volatile memory is a NOR flash memory.
